(19) United States
(12) Patent Application Publication
(10) Pub. No.: US 2010/0164776 A1
(43) Pub. Date: Jul. 1, 2010

(54) SOURCE DRIVER IN DISPLAY

(76) Inventors: Shin-Young Yi, Seongnam-si (KR); Yong-In Park, Gangnam-gu (KR); Tae-Woon Kim, Anyang-si (KR); Sang-Hoon Lim, Jungnang-gu (KR); Jin Seok Koh, Yongin-si (KR)

Correspondence Address: SHERR & VAUGHN, PLLC, 620 HERNDON PARKWAY, SUITE 320, HERNDON, VA, 20170, US

(21) Appl. No.: 12/644,333

(22) Filed: Dec. 22, 2009

(30) Foreign Application Priority Data
Dec. 30, 2008 (KR) 10-2008-0136378

(51) Int. Cl. H03M 3/00

(52) U.S. Cl. 341/143

(57) ABSTRACT

A source driver in a display may include a latch capable of latching input data received from a timing controller in a display, a delta-sigma digital-to-analog converter configured to convert the input data stored in the latch to an analog signal by delta-sigma modulation, and an output buffer configured to output a column drive signal by buffering the analog signal received from the delta-sigma digital-to-analog converter. Accordingly, a source driver in a display modulates input data of 10-bit or higher by delta-sigma modulation with high accuracy, and then converts the data to an analog signal. Therefore, although an area occupied by the source driver of embodiments becomes smaller than that occupied by the related art source driver with a high resolution of 10-bits or higher, a display panel can provide an image of high resolution.

The present application claims priority under 35 U.S.C. 119 to Korean Patent Application No. 10-2008-0136378 (filed on Dec. 30, 2008), which is hereby incorporated by reference in its entirety.

### BACKGROUND

A source driver drives a display panel of a flat panel display (hereinafter called a display). The source driver may use an R-string digital-to-analog converter (DAC). The demand for development of a source driver integrated circuit (IC) is rising according to the ongoing development of video technology.

In the following description, a display source driver according to a related art is explained with reference to the accompanying drawing. FIG. 1 is a block diagram of a source driver according to a related art. The source driver may include of a latch 10, an R-string DAC 20 and an output buffer 30.

Referring to FIG. 1, the source driver receives a plurality of N-bit data 5 from a timing controller (not shown in the drawing). In this case, N is equal to 10, for example. The R-string DAC 20 converts the data received from the latch 10 to an analog signal. In this case, the number of resistors is 2×2N to implement the R-string DAC 20. If input resolution is increased from 8-bit to 10-bit, an area occupied by the resistors is increased by 4 times. Moreover, a line for connecting the R-string DAC to a core DAC (not shown in the drawing) is increased by 4 times as well. Thus, the implementation of the DAC 20 adopting the R-string structure has limitation in being applied to video technology that requires high resolution.

### SUMMARY

Embodiments relate to a display, and more particularly, to a source driver in a display. Embodiments relate to a source driver in a display which occupies less area while maintaining high accuracy.

Embodiments relate to a source driver in a display which may include a latch capable of latching input data received from a timing controller in a display, a delta-sigma digital-to-analog converter configured to convert the input data stored in the latch to an analog signal by delta-sigma modulation, and an output buffer configured to output a column drive signal by buffering the analog signal received from the delta-sigma digital-to-analog converter.

Accordingly, embodiments may provide the following advantages. A source driver in a display according to embodiments modulates input data of 10-bit or higher by delta-sigma modulation with high accuracy, and then converts the data to an analog signal. Therefore, although an area occupied by the source driver of embodiments becomes smaller than that occupied by the related art source driver having high resolution of 10-bit or higher, a panel can provide an image of high resolution.

### DRAWINGS

FIG. 1 is a block diagram of a source driver according to a related art.

Example FIG. 2 is a schematic block diagram of a source driver in a display according to embodiments.

Example FIG. 3 is a block diagram of a delta-sigma DAC shown in example FIG. 2 according to embodiments.

Example FIG. 4 is a block diagram of a modulating unit shown in example FIG. 3 according to embodiments.

Example FIG. 5 is a block diagram of a modulating unit shown in example FIG. 3 according to embodiments.

Example FIG. 6A and example FIG. 6B are graphs for power spectrum density of signals outputted from a modulating unit.

Example FIG. 7 is a diagram for circuitry of a core DAC and an analog filter shown in example FIG. 3 according to embodiments.

### DESCRIPTION

A display may include a timing controller, a display panel, a source driver (or a column driver), and a gate driver (or a row driver). The timing controller controls the source driver and the gate driver. The source and gate drivers play a role in driving a display panel. The display panel displays an image according to a scan signal outputted from the gate driver and a data signal outputted from the source driver. The display panel can include one of various display panels usable between the timing controller 300 and a display drive integrated (DDI) circuit. The display panel may include an LCD panel such as a TFT-LCD (TFT Liquid Crystal Display) panel, an STN-LCD panel, a FLCD (ferroelectric LCD) panel and the like, a PDP (plasma display panel), an OLED (Organic Luminescence Electro Display) panel, an FED panel or the like.

A source driver in a display according to embodiments is explained with reference to the accompanying drawings as follows. Example FIG. 2 is a block diagram of a source driver in a display according to embodiments. The source driver may include a latch 10, an R-string DAC 200 and an output buffer 200.

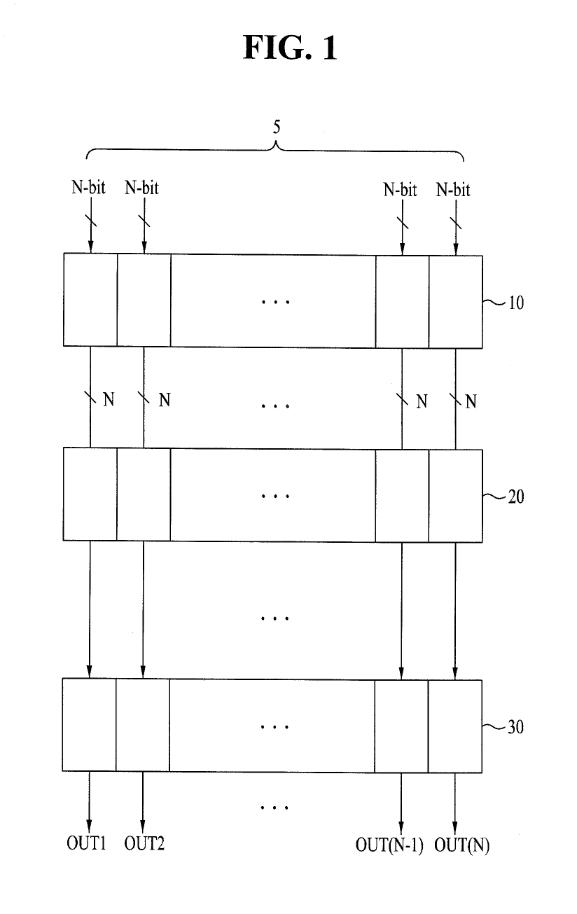

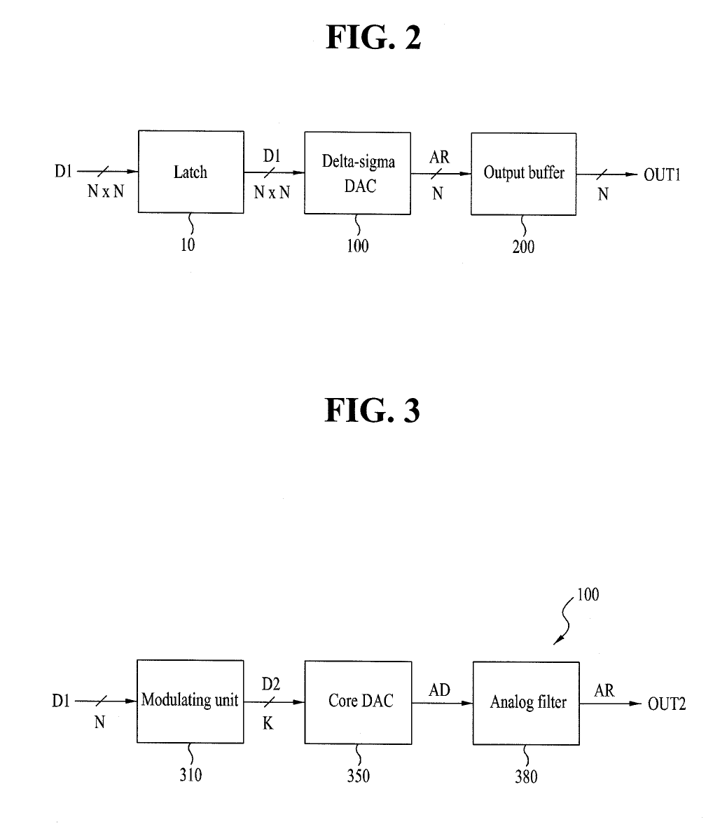

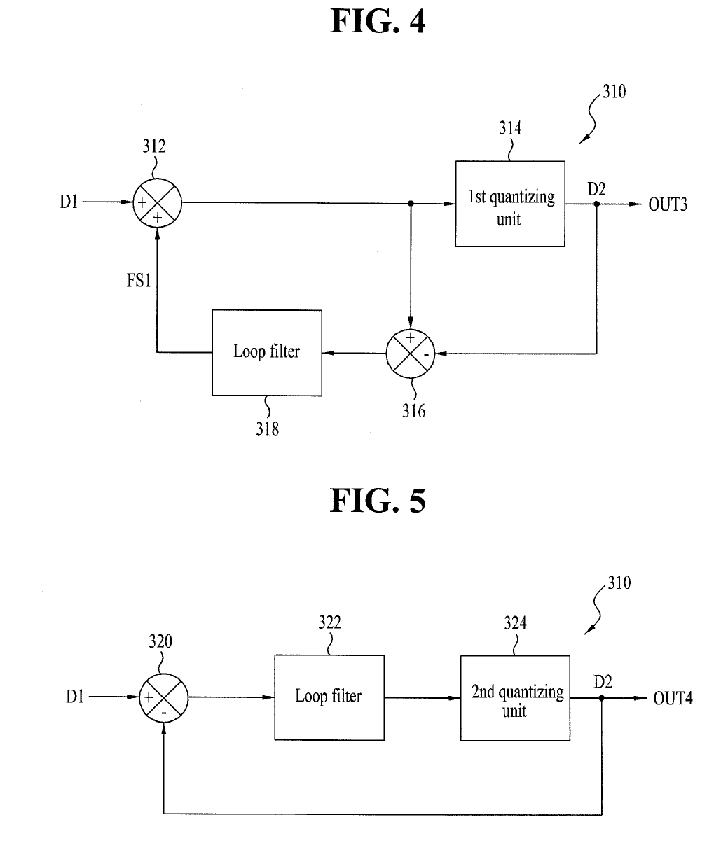

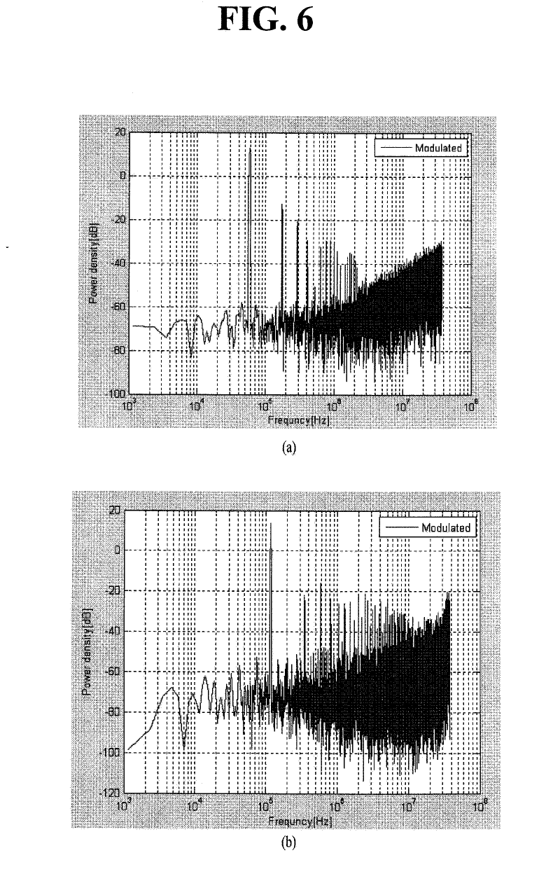

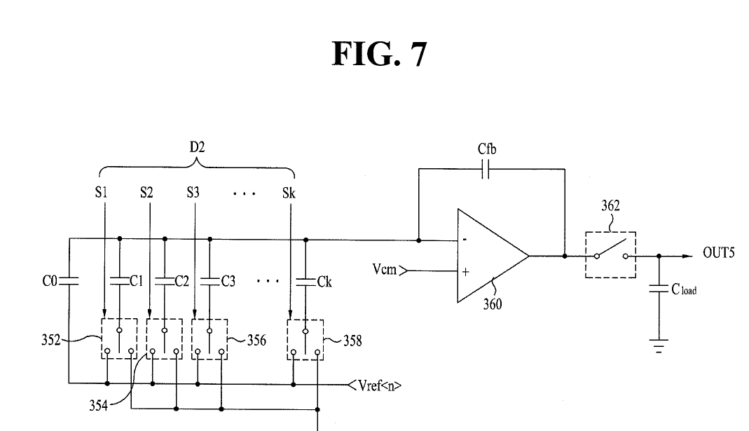

The latch and output buffer 10 and 200 shown in example FIG. 2 may have the same configurations and operations of the related latch and output buffer 10 and 30 shown in FIG. 1. In particular, the latch 10 may receive N input data of N bit per pixel (or per column of display panel) from the timing controller, and then store the received data. Therefore, if the number of columns is N, the latch can store N×N input data Dl.

The delta-sigma DAC 100 may convert the digital input data D1 stored in the latch 10 to an analog signal AR by delta-sigma modulation. Then the converted analog signal AR may be output to the output buffer 200. In this case, the delta-sigma DAC 100 processes the stored input data D1 by N bits each. If N is equal to or greater than 10, N bits of the digital input data D1 having resolution of N bits or higher may be brought from the latch 10. In particular, the input data D1 entering the delta-sigma DAC 100 is already oversampled with high frequency.

A process for the delta-sigma DAC 100 to convert input data D1 to an analog signal (A) by N bits according to embodiments is explained with reference to the accompanying drawings as follows. Example FIG. 3 is a block diagram of a delta-sigma DAC shown in example FIG. 2 according to embodiments. The delta-sigma DAC 100 may include a modulating unit 310, a core DAC 350 and an analog filter 380.

The modulating unit 310 shown in example FIG. 3 may receive the input data D1 stored in the latch 10 and modulate the received data by N bits each. The modulating unit 310 then outputs K-bit digital signal D2 to the core DAC 350 according to a result of the modulation. In this case, K is smaller than N.

Example FIG. 4 is a block diagram of the modulating unit 310 shown in example FIG. 3 according to embodiments. The modulating unit 310 may include an adding unit 312, a first quantizing unit 314, a first subtracting unit 316 and a loop filter 318. The adding unit 312 adds the N-bit input data brought from the latch 10 to a feedback signal FS and then outputs the added result to the first quantizing unit 314 and the first subtracting unit 316.

The first quantizing unit 314 quantizes the result added by the adding unit 312 and then outputs the quantized result to an output D2 of the modulating unit 310. The first subtracting unit 316 subtracts the result D2 quantized by the quantizing unit 314 from the result (D1+FS1) added by the adding unit 312 and then outputs the subtracted result (D1+FS1−D2) to the loop filter 318. The loop filter 318 filters the result (D1+FS1−D2) subtracted by the subtracting unit 316 and then outputs the filtered result as a feedback signal FS1 to the adding unit 312. In this case, the loop filter 318 plays a role in adjusting an integration factor to enable the modulating unit 310 shown in example FIG. 4 to play a role as an integrator.

Example FIG. 5 is a block diagram of the modulating unit 310 shown in example FIG. 3 according to embodiments. The modulating unit 310 includes a second subtracting unit 320, a loop filter 322 and a second quantizing unit 324.

The second subtracting unit 320 receives N-bit input data D1 from the latch 10, subtracts an output D2 of the second quantizing unit 324 from the N-bit input data, and then outputs the subtracted result to the loop filter 322. The loop filter 322 filters the result subtracted by the second subtracting unit 320 and then outputs the filtered result to the second quantizing unit 324. In this case, the function of the loop filter 322 is identical to that of the former loop filter 318 shown in example FIG. 4. In particular, the loop filter 322 plays a role in adjusting an integration factor to enable the modulating unit 310 shown in example FIG. 5 to play a role as an integrator. The second quantizing unit 324 quantizes the result filtered by the loop filter 322 and then outputs the quantized result as a result D2 modulated by the modulating unit 310.

From the above description, it can be observed that the N-bit input data D1 is transformed into K-bit data D2 through the modulating unit 310 [K<N]. In this transforming process, quantization noise generated from the first/second quantizing unit 314/324 is shaped by a noise shaping function. Namely, error attributed to quantization can be compensated by the noise shaping.

Example FIG. 6A and example FIG. 6B are graphs for power spectrum density of signals outputted from the modulating unit 310, in which horizontal and vertical axes indicate frequency and power density, respectively. Example FIG. 6A shows 1st order power density and example FIG. 6B shows 2nd order power density.

From FIG. 6A and example FIG. 6B, it can be observed that high quantization noise level exists in a high frequency region. This is attributed to the noise shaping property of the modulator of the delta-sigma type. The noise generated from the high frequency band can be removed by the analog filter 380 shown in example FIG. 3 and a parasitic manual filter of a flat panel display, which are described in the following description.

The core DAC 350 shown in example FIG. 3 converts the K-bit digital signal D2 modulated by the modulating unit 310 to an analog signal AD and then outputs the converted analog signal Ad to the analog filter 380. The analog filter 380 removes the noise of the analog signal AD outputted from the core DAC 350 and then outputs a noise-free analog signal AR.

Example FIG. 7 is a diagram for circuitry of the core DAC 350 and the analog filter 380 shown in example FIG. 3 according to embodiments, which may include K switching devices 352 to 358, a capacitor C0, 1st to Kth capacitors C1 to CK, an operation amplifier 360, a feedback capacitor Cfb, a load capacitor Cload, and a switch 362. The DAC shown in example FIG. 7 is a binary capacitor type DAC. Yet, the core DAC 350 shown in example FIG. 3 can be implemented by any commonly used DAC unlike the DAC shown in example FIG. 7.

The K switching devices 352 to 358 switch between a reference voltage (Vref<n>) and a ground voltage in response to K-bit digital signals (D2=S1 to Sk) modulated by the modulating unit 310, respectively. The operational amplifier 360 has an output terminal connected to an output of the analog filter 380, a positive input terminal (or non-inverting input +) connected to a common voltage Vcm and a negative input terminal (or inverting input terminal −) connected to the switching devices 352 to 358.

The capacitor C0 is connected between the negative input terminal (−) of the operational amplifier 360 and the reference voltage Vref<n>. The 1st to Kth capacitors C1 to CK may be connected to the negative input terminal (−) of the operational amplifier 360 and the K switching devices 352 to 358, respectively. The feedback capacitor Cfb is connected between the negative input terminal (−) and the output terminal of the operational amplifier 360. Also, a switching device 362 outputting an analog signal, which is an output of the operational amplifier 360, to an output terminal OUTS through switching and a load capacitor Cload can be further included.

As mentioned in the foregoing description, an analog signal for N input data may be outputted to the delta-sigma DAC 100 one by one. Meanwhile, the output buffer 200 buffers N analog signals AR received from the delta-sigma DAC 100 and then outputs the buffered signals as column drive signals to the display panel via an output terminal OUTPUT1.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a latch capable of latching input data received from a timing controller in a display;
a delta-sigma digital-to-analog converter configured to convert the input data stored in the latch to an analog signal by delta-sigma modulation; and
an output buffer configured to output a column drive signal by buffering the analog signal received from the delta-sigma digital-to-analog converter.

2. The apparatus of claim 1, wherein the delta-sigma digital-to-analog converter includes a modulating unit.

3. The apparatus of claim 2, wherein the modulating unit is configured to modulate the N-bit input data stored in the latch, and output a modulated K-bit digital signal (K<N).

4. The apparatus of claim 3, wherein the delta-sigma digital-to-analog converter includes a core digital-to-analog converting unit.

5. The apparatus of claim 4, wherein the core digital-to-analog converting unit is configured to convert the modulated K-bit digital signal to the analog signal.

6. The apparatus of claim 5, wherein the delta-sigma digital-to-analog converter includes an analog filter.

7. The apparatus of claim 6, wherein the analog filter is configured to remove noise of the analog signal outputted from the core digital-to-analog converting unit.

8. The apparatus of claim 3, wherein the modulating unit includes an adding unit adding the N-bit input data to a feedback signal.

9. The apparatus of claim 8, wherein the modulating unit includes a first quantizing unit outputting the modulated K-bit digital signal by quantizing a result added by the adding unit.

10. The apparatus of claim 9, wherein the modulating unit includes:
a first subtracting unit subtracting the quantized result from the subtracted result.

11. The apparatus of claim 10, wherein the modulating unit includes a loop filter outputting the feedback signal by filtering the result subtracted by the first subtracting unit.

12. The apparatus of claim 10, wherein the modulating unit includes a second subtracting unit subtracting the modulated K-bit digital signal from the N-bit input data.

13. The apparatus of claim 12, wherein the modulating unit includes a loop filter filtering a result subtracted by the second subtracting unit.

14. The apparatus of claim 13, wherein the modulating unit includes a second quantizing unit outputting the modulated K-bit digital signal by quantizing a result filtered by the loop filter.

15. The apparatus of claim 6, wherein the core digital-to-analog converting unit and the analog filter includes K switching devices.

16. The apparatus of claim 15, wherein the K switching devices are configured to switch between a reference voltage and a ground voltage in response to the K-bit modulated digital signal.

17. The apparatus of claim 6, wherein the core digital-to-analog converting unit and the analog filter includes an operational amplifier having an output terminal connected to an output of the analog filter.

18. The apparatus of claim 17, wherein the operational amplifier has a positive input terminal connected to a common voltage and a negative input terminal connected to each of the switching devices.

19. The apparatus of claim 18, wherein the core digital-to-analog converting unit and the analog filter includes 1^{st} to K^{th} capacitors connected between the negative input terminal and the K switching devices, respectively.

20. The apparatus of claim 19, wherein the core digital-to-analog converting unit and the analog filter includes a (K+1)^{th} capacitor connected between the negative input terminal and the output terminal of the operational amplifier.
